(19) United States
(12) Patent Application Publication
(10) Pub. No.: US 2024/0194780 A1
(43) Pub. Date: Jun. 13, 2024

(54) SEMICONDUCTOR DEVICE AND POWER CONVERSION APPARATUS

(71) Applicant: Mitsubishi Electric Corporation, Tokyo (JP)

(72) Inventors: Kohei ADACHI, Tokyo (JP); Yutaka FUKUI, Tokyo (JP)

(73) Assignee: Mitsubishi Electric Corporation, Tokyo (JP)

(21) Appl. No.: 18/287,650

(22) PCT Filed: May 27, 2021
(86) PCT No.: PCT/JP2021/020212

§ 371 Date: Oct. 20, 2023

(51) Int. Cl. H01L 29/78; H01L 27/088; H01L 29/06

(52) U.S. Cl. CPC H01L 29/7813; H01L 27/088; H01L 29/0619

(57) ABSTRACT

An object of the present invention is to provide a technique capable of reducing an energy loss during a switching operation. A first peripheral region includes a second bottom protection layer of a second conductivity type provided at a bottom of a second trench, and a second peripheral region includes a third bottom protection layer of the second conductivity type provided at a bottom of a third trench. The second bottom protection layer is electrically connected to a source electrode, the third bottom protection layer is electrically connected to a current sense electrode, or the second bottom protection layer and the third bottom protection layer are respectively electrically connected to the source electrode and the current sense electrode.

### TECHNICAL FIELD

The present disclosure relates to a semiconductor device and a power conversion apparatus.

### BACKGROUND ART

In power electronic devices, switching devices such as an insulated gate bipolar transistor (IGBT) and a metal oxide semiconductor field effect transistor (MOSFET) are used as means for switching between execution and stopping of power supply for driving a load such as an electric motor.

As a switching device assumed to be used as a power semiconductor device, a vertical MOSFET and a vertical IGBT having a vertical structure are often adopted. For example, as a vertical MOSFET, a MOSFET such as a planar type and a trench type (sometimes referred to as a trench gate type) having different gate structures is known.

In a trench gate type MOSFET in which a gate trench as a groove portion is formed in an active region of an n-type drift layer, due to its structure, there is a possibility that a high electric field may be applied to a gate insulating film at a bottom of the gate trench in an Off state, and thus a defect may occur in a gate insulating film. For this problem, for example, Patent Document 1 proposes a configuration in which a protective diffusion layer such as a p-type electric field relaxation region is provided to cover a gate trench bottom to relax an electric field applied to a gate insulating film at the gate trench bottom.

Patent Document 1 proposes a technique in which a sense cell for detecting an overcurrent is mounted on the same semiconductor chip in order to curb the occurrence of failures in a device due to a surge overcurrent at the time of a switching operation and an overcurrent at the time of a gate short circuit. As a structure of the sense cell, a structure having a MOSFET region having a small size in which the influence of heat generation due to an overcurrent is suppressed and having a structure similar to that of a main cell in an active region is used. The main cell and the sense cell are mounted in the same chip, but are electrically separated because separate current paths are required.

### PRIOR ART DOCUMENT

### Patent Document

Patent Document 1: Japanese Patent No. 4500639

### SUMMARY

### Problems to be Solved by the Invention

In the technique in Patent Document 1, in order to electrically separate a main cell and a sense cell, a trench serving as a dummy and a bottom protection layer at the bottom thereof are provided between these cells. However, in such a structure, since the bottom protection layer is in a floating potential state, there is a problem that an energy loss during a switching operation increases.

Therefore, the present disclosure has been made in view of the above problems, and an object thereof is to provide a technique capable of reducing an energy loss during a switching operation.

### Means to Solve the Problem

A semiconductor device according to the present disclosure includes a main cell region and a sense cell region that are separated from each other; a first peripheral region that is adjacent to the main cell region between the main cell region and the sense cell region; a second peripheral region that is adjacent to the sense cell region between the main cell region and the sense cell region; and a separation region that separates the first peripheral region and the second peripheral region from each other. The main cell region, the first peripheral region, the separation region, the second peripheral region, and the sense cell region include a drift layer of a first conductivity type. Each of the main cell region and the sense cell region includes a body region of a second conductivity type that is provided on the drift layer, a source region of the first conductivity type that is provided on the body region, a first trench that penetrates the body region and the source region and is partially in contact with the drift layer, a gate electrode that is provided in the first trench via a gate insulating film, a first bottom protection layer of the second conductivity type that is provided at a bottom of the first trench, and a connection layer of the second conductivity type that is provided along at least a part of a sidewall of the first trench and connects the first bottom protection layer and the body region. The main cell region further includes a source electrode that is connected to the source region. The sense cell region further includes a current sense electrode that is connected to the source region and separate from the source electrode. The first peripheral region further includes a second trench that is provided above the drift layer and is wider than the first trench; and a second bottom protection layer of the second conductivity type that is provided at the bottom of the second trench. The second peripheral region further includes a third trench that is provided above the drift layer and is wider than the first trench, and a third bottom protection layer of the second conductivity type that is provided at the bottom of the third trench. The second bottom protection layer is electrically connected to the source electrode, the third bottom protection layer is electrically connected to the current sense electrode, or the second bottom protection layer and the third bottom protection layer are respectively electrically connected to the source electrode and the current sense electrode.

### Effects of the Invention

According to the present disclosure, the second bottom protection layer is electrically connected to the source electrode, the third bottom protection layer is electrically connected to the current sense electrode, or the second bottom protection layer and the third bottom protection layer are respectively electrically connected to the source electrode and the current sense electrode. Consequently, an energy loss during a switching operation can be reduced.

Objects, features, aspects, and advantages of the present disclosure will become more apparent from the following detailed description and the accompanying drawings.

### BRIEF DESCRIPTION OF DRAWINGS

FIG. 1 is a schematic plan view illustrating a configuration of a semiconductor device according to a first embodiment.

FIG. 2 is a schematic sectional view illustrating a configuration of the semiconductor device according to the first embodiment.

FIG. 3 is a schematic sectional view illustrating a configuration of a semiconductor device according to a first modification example.

FIG. 4 is a schematic sectional view illustrating a configuration of a semiconductor device according to a second modification example.

FIG. 5 is a schematic sectional view illustrating a configuration of a semiconductor device according to a third modification example.

FIG. 6 is a schematic sectional view illustrating a configuration of the semiconductor device according to the third modification example.

FIG. 7 is a schematic sectional view illustrating a method of manufacturing the semiconductor device according to the first embodiment.

FIG. 8 is a schematic sectional view illustrating the method of manufacturing the semiconductor device according to the first embodiment.

FIG. 9 is a schematic sectional view illustrating the method of manufacturing the semiconductor device according to the first embodiment.

FIG. 10 is a schematic sectional view illustrating the method of manufacturing the semiconductor device according to the first embodiment.

FIG. 11 is a schematic sectional view illustrating the method of manufacturing the semiconductor device according to the first embodiment.

FIG. 12 is a schematic sectional view illustrating the method of manufacturing the semiconductor device according to the first embodiment.

FIG. 13 is a schematic sectional view illustrating the method of manufacturing the semiconductor device according to the first embodiment.

FIG. 14 is a schematic plan view illustrating a configuration of a semiconductor device according to a second embodiment.

FIG. 15 is a schematic sectional view illustrating a configuration of the semiconductor device according to the second embodiment.

FIG. 16 is a schematic plan view illustrating a configuration of a semiconductor device according to a third embodiment.

FIG. 17 is a schematic sectional view illustrating a configuration of the semiconductor device according to the third embodiment.

FIG. 18 is a schematic plan view illustrating a configuration of a semiconductor device according to a fourth embodiment.

FIG. 19 is a schematic sectional view illustrating a configuration of the semiconductor device according to the fourth embodiment.

FIG. 20 is a schematic diagram illustrating a configuration of a power conversion apparatus diagram according to a fifth embodiment.

### DESCRIPTION OF EMBODIMENTS

Hereinafter, embodiments will be described with reference to the accompanying drawings. Features described in the following embodiments are examples, and all features are not necessarily essential. In the following description, similar constituents in a plurality of embodiments are denoted by the same or similar reference numerals, and different constituents will be mainly described. In the following description, specific positions and directions such as “upper”, “lower”, “left”, “right”, “front”, and “back” may not necessarily coincide with actual positions and directions in practice. The fact that a certain portion has a higher concentration than another portion means that, for example, an average of concentrations of the certain portion is higher than an average of concentrations of another portion. Conversely, the fact that a certain portion has a lower concentration than another portion means that, for example, an average of concentrations of the certain portion is lower than an average of concentrations of another portion. In the following description, the first conductivity type is n-type and the second conductivity type is p-type, but the first conductivity type may be p-type and the second conductivity type may be n-type.

### First Embodiment

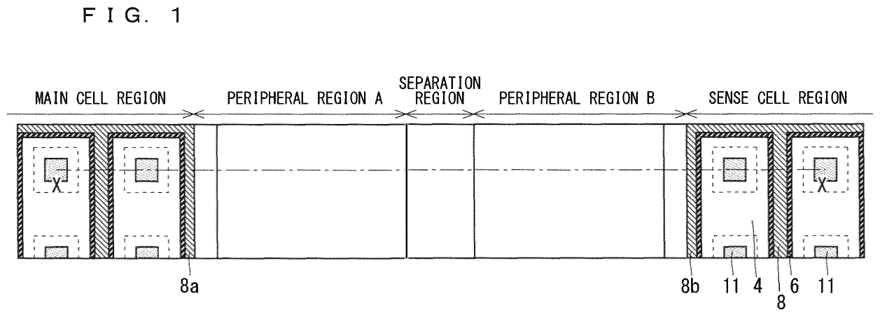

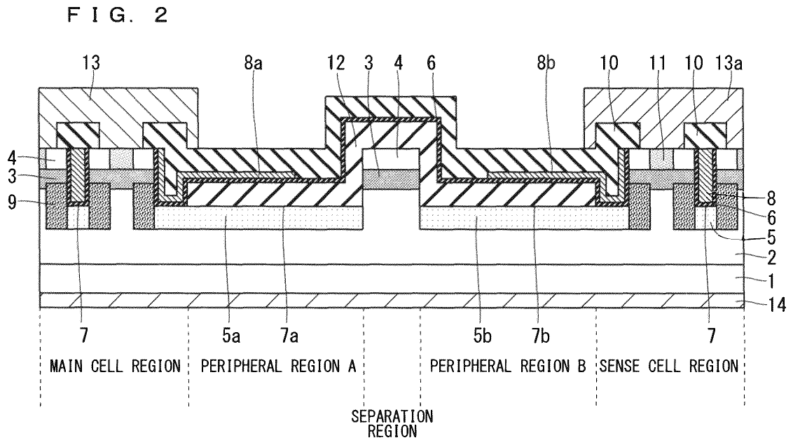

FIG. 1 is a schematic plan view illustrating a configuration of a semiconductor device according to a first embodiment, and FIG. 2 is a schematic sectional view taken along line X-X in FIG. 1. Hereinafter, the semiconductor device according to the first embodiment will be described as a trench-type MOSFET containing silicon carbide (SIC).

As illustrated in FIGS. 1 and 2, the MOSFET according to the first embodiment includes a main cell region (also referred to as a MOSFET region), a sense cell region, a peripheral region A as a first peripheral region, a peripheral region B as a second peripheral region, and a separation region.

The main cell region and the sense cell region are separated from each other. The peripheral region A is adjacent to the main cell region between the main cell region and the sense cell region. The peripheral region B is adjacent to the sense cell region between the main cell region and the sense cell region. The separation region is located at a boundary between the peripheral region A and the peripheral region B, and separates the peripheral region A and the peripheral region B.

Hereinafter, a configuration of the main cell region will be mainly described, and description of other regions will be omitted as appropriate. Note that, since the constituents of the main cell region and the constituents of the sense cell region are substantially the same, in FIGS. 1 and 2, reference numerals of some of the constituents are given to only one of the main cell region and the sense cell region.

### <Main Cell Region>

As illustrated in FIG. 2, the MOSFET according to the first embodiment includes an epitaxial substrate including an n-type SiC substrate 1 and an n-type SiC epitaxial layer (semiconductor layer) grown thereon. A base region 3 that is a p-type body region, an n-type source region 4, and a p-type well contact layer 11 are provided above the epitaxial layer in the main cell region. The drift layer 2 is an n-type region below the base region 3 in the epitaxial substrate, and is included in at least one of the SiC substrate 1 or the epitaxial layer. As described above, the main cell region includes the SiC substrate 1, the drift layer 2, the base region 3, the source region 4, and the well contact layer 11.

The well contact layer 11 has a higher p-type impurity concentration than that of the base region 3. A depth of the well contact layer 11 is the same as or larger than that of the source region 4, and the well contact layer 11 is in contact with the base region 3. As illustrated in FIG. 1, the well contact layer 11 is selectively (partially) provided in the source region 4 in a plan view, and is surrounded by the source region 4. In FIG. 1, a shape of the well contact layer 11 in a plan view is a dot shape, but may be a stripe shape.

As illustrated in FIG. 2, the main cell region includes a bottom protection layer that is a first bottom protection layer, a gate oxide film 6 that is a gate insulating film, a trench 7 that is a first trench, a polysilicon electrode 8 that is a gate electrode, a sidewall connection layer 9 that is a connection layer, an interlayer oxide film 10, a source electrode 13, and a drain electrode 14.

The trench 7 penetrates the base region 3 and the source region 4, reaches the drift layer 2, and is partially in contact with the drift layer 2. The gate oxide film 6 is provided to cover a sidewall and a bottom of the trench 7, and the polysilicon electrode 8 is embedded in the trench 7 via the gate oxide film 6. The gate electrode is not limited to the polysilicon electrode 8, and may be a metal electrode.

The polysilicon electrode 8 embedded in the trench 7 is electrically connected to a gate pad (not illustrated) of the MOSFET. The electrical connection between a first constituent and a second constituent means that the first constituent and the second constituent are not insulated from each other.

The p-type bottom protection layer 5 is provided at the bottom of the trench 7. Note that the bottom protection layer 5 may be provided at least at a part of the bottom of the trench 7. The bottom protection layer 5 may be periodically provided, for example, in a longitudinal direction (depth direction in FIG. 2) of the trench 7, or may be provided in a half of the bottom of the trench 7 in a cross section intersecting the longitudinal direction. The bottom protection layer 5 may be provided at the entire bottom of the trench 7, or may be provided to protrude to the drift layer 2 while being provided at the bottom of the trench 7.

The p-type sidewall connection layer 9 is provided along at least a part of the sidewall of the trench 7. The sidewall connection layer 9 may be provided only on one sidewall of the trench 7 or may be provided on both sidewalls. The sidewall connection layer 9 connects the bottom protection layer 5 to the base region 3. The sidewall connection layer 9 may be disposed at any period in the longitudinal direction of the trench 7.

The interlayer oxide film 10 is provided on an upper surface of the epitaxial layer and covers the polysilicon electrode 8. The interlayer oxide film 10 is provided with a contact hole reaching the source region 4 and the base region 3, and a low-resistance ohmic electrode (not illustrated) is provided in the contact hole.

The source electrode 13 is connected to the source region 4 and the well contact layer 11 in the main cell region. In the first embodiment, the source electrode 13 has a portion on the interlayer oxide film 10 and the ohmic electrode in a contact hole of the interlayer oxide film 10.

The drain electrode 14 is provided on a lower surface of the SiC substrate 1 and is made of an electrode material such as an aluminum (Al) alloy.

In FIG. 1, the polysilicon electrode 8 is disposed in a stripe shape in a plan view. In the main cell region, the polysilicon electrode 8 and its peripheral portion function as a MOSFET. In general, the SiC substrate 1 has a surface that is angled at 4° with respect to a (0001) face that is a c-face of a SiC crystal. This is for growing a crystal having a desired crystal structure in a SiC crystal having a crystal polymorphism. In a configuration in which the stripe-shaped trench 7 is disposed in parallel to the off-angle, an atomic layer step does not occur at the interface between the gate oxide film 6 and SiC, but an atomic layer step occurs at the interface when the stripe-shaped trench 7 is disposed vertically. The presence of the atomic layer step affects the number of interface states, and a gate breakdown voltage is higher in the configuration in which the trench 7 is disposed in parallel to the off-angle. Therefore, it is desirable that the stripe-shaped trench 7 constituting the main cell region is disposed in parallel to the off-angle. However, even if the trench 7 is not disposed with respect to the off-angle as described above, it is possible to suppress a decrease in the gate breakdown voltage by disposing the above-described sidewall connection layer 9 intensively on a surface having a large number of interface states or on the entire surface.

Although the thickness of the side portion and the thickness of the bottom of the gate oxide film 6 illustrated in FIG. 2 are the same, the film thickness of the gate oxide film 6 in contact with the bottom of the polysilicon electrode 8 may be larger than the film thickness of the gate oxide film 6 in contact with the side portion of the polysilicon electrode 8. Actually, only a portion in contact with the side portion of the polysilicon electrode 8 functions as the gate oxide film 6 in an operation of the MOSFET, and the portion in contact with the bottom does not contribute to the operation of the MOSFET. An electric field is likely to concentrate at the bottom of the trench 7, and a failure is likely to occur in the gate oxide film 6. Therefore, in addition to the disposition of the bottom protection layer 5, by making the portion of the gate oxide film 6 in contact with the bottom of the polysilicon electrode 8 thicker than the other portions, an electric field applied to the gate oxide film 6 can be further alleviated.

### <Sense Cell Region>

The sense cell region has the same configuration as that of the main cell region, and is provided on the same semiconductor chip as the main cell region. The sense cell region includes a SiC substrate 1, a drift layer 2, a base region 3, a source region 4, a bottom protection layer 5, a gate oxide film 6, a trench 7, a polysilicon electrode 8, a sidewall connection layer 9, an interlayer oxide film 10, a well contact layer 11, and a drain electrode 14.

However, the sense cell region includes a current sense electrode 13a instead of the source electrode 13. The current sense electrode 13a is an individual electrode electrically separated from the source electrode 13, and is connected to the source region 4 and the well contact layer 11 in the sense cell region. In the first embodiment, the current sense electrode 13a includes a portion on the interlayer oxide film 10 and an ohmic electrode (not illustrated) in a contact hole of the interlayer oxide film 10.

The sense cell region has a smaller area than that of the main cell region, and an amount of current that can flow in the sense cell region is smaller than that in the main cell region. On the other hand, since the sense cell region has the same structure as that of the main cell region, there is a certain correlation between a current flowing through the sense region and a current flowing through the main cell region. Thus, a large current flowing through the main cell region can be detected on the basis of a small current flowing through the sense region.

A current flowing through the main cell region is detected on the basis of a signal of a minute current flowing through the current sense electrode 13a in the sense cell region, and an operation of the MOSFET is suppressed in a case where the detected current is equal to or more than the threshold value. According to such a configuration, when an overcurrent flows in the main cell region, it is possible to suppress a problem occurring in the main cell region due to heat generation due to a size of an area and a large amount of current.

### <Peripheral Region A>

The peripheral region A adjacent to the main cell region includes a SiC substrate 1, a drift layer 2, a bottom protection layer 5a as a second bottom protection layer, a gate oxide film 6, a trench 7a as a second trench, a capacitance electrode 8a, an interlayer oxide film 10, a field insulating film 12, and a drain electrode 14. A width of the peripheral region A is, for example, 5 μm to 100 μm.

The trench 7a penetrates the base region 3 and the source region 4 similarly to the trench 7, and is provided above the drift layer 2. A width of the trench 7a is larger than a width of the trench 7 in the main cell region and the sense cell region.

The p-type bottom protection layer 5a is provided at the bottom of the trench 7a and is electrically connected to the source electrode 13. In the first embodiment, the bottom protection layer 5a is connected to the source electrode 13 via the sidewall connection layer 9, the base region 3, and the well contact layer 11.

The gate oxide film 6 and the field insulating film 12 are selectively provided on the bottom protection layer 5a. The capacitance electrode 8a is provided on the gate oxide film 6. As illustrated in FIG. 1, the capacitance electrode 8a is a part of the polysilicon electrode 8, and is connected to the polysilicon electrode 8 in the trench 7 in the main cell region. As illustrated in FIG. 2, the interlayer oxide film 10 covers the gate oxide film 6, the field insulating film 12, and the capacitance electrode 8a.

### <Peripheral Region B>

The peripheral region B adjacent to the sense cell region has a configuration similar to that of the peripheral region A. Specifically, the peripheral region B includes a SiC substrate 1, a drift layer 2, a bottom protection layer 5b as a third bottom protection layer, a gate oxide film 6, a trench 7b as a third trench, a capacitance electrode 8b, an interlayer oxide film 10, a field insulating film 12, and a drain electrode 14. The width of the peripheral region B is, for example, 5 μm to 100 μm.

The trench 7b penetrates the base region 3 and the source region 4 similarly to the trench 7, and is provided above the drift layer 2. A width of the trench 7b is larger than a width of the trench 7 in the main cell region and the sense cell region.

The p-type bottom protection layer 5b is provided at the bottom of the trench 7b and is electrically connected to the current sense electrode 13a. In the first embodiment, the bottom protection layer 5b is connected to the current sense electrode 13a via the sidewall connection layer 9, the base region 3, and the well contact layer 11.

The gate oxide film 6 and the field insulating film 12 are selectively provided on the bottom protection layer 5b. The capacitance electrode 8b is provided on the gate oxide film 6. As illustrated in FIG. 1, the capacitance electrode 8b is a part of the polysilicon electrode 8, and is connected to the polysilicon electrode 8 in the trench 7 in the sense cell region. The capacitance electrodes 8a and 8b may be common electrodes connected to metal electrodes (not illustrated) having the same potential located at both ends in an extending direction in a left-right direction or a depth direction in FIG. 2. As illustrated in FIG. 2, the interlayer oxide film 10 covers the gate oxide film 6, the field insulating film 12, and the capacitance electrode 8b.

According to the configuration of the peripheral region A and the peripheral region B as described above, the bottom protection layer 5a is electrically connected to the source electrode 13, and the bottom protection layer 5b is electrically connected to the current sense electrode 13a. According to such a configuration, since the bottom protection layers 5a and 5b are not in a floating potential state, an energy loss during a switching operation can be reduced.

Note that a breakdown voltage of the MOSFET depends on a depth of the trench. Thus, the depth of the trench 7a in the peripheral region A, the depth of the trench 7b of the peripheral region B, the depth of the trench 7 in the main cell region, and the depth of the trench 7 in the sense cell region are desirably the same. According to such a configuration, the breakdown voltage can be increased. Note that, in a configuration in which the depths of the trenches are different, it is desirable to change formation conditions such as impurity concentrations and depths for the bottom protection layer Sa of the peripheral region A, the bottom protection layer 5b of the peripheral region B, the bottom protection layer 5 in the main cell region, and the bottom protection layer 5 in the sense cell region.

### <Separation Region>

The separation region includes a SiC substrate 1, a drift layer 2, a base region 3, a source region 4, a gate oxide film 6, an interlayer oxide film 10, a field insulating film 12, and a drain electrode 14. A mesa 70 is provided between the peripheral region A and the peripheral region B. In the first embodiment, the mesa 70 includes the drift layer 2, the base region 3, and the source region 4. According to the configuration in which the mesa 70 includes the base region 3 as in the first embodiment, it is possible to suppress a decrease in a breakdown voltage and an increase in an oxide film electric field around the separation region. In the first embodiment, the mesa 70 includes the source region 4, but does not need to include the source region 4. In the separation region, a trench for electrically separating the bottom protection layer 5a and the bottom protection layer 5b may be provided instead of the mesa 70, or an insulating layer may be provided in the trench.

A region between the trench 7a and the trench 7b is separated by the mesa 70. The bottom protection layers 5a and 5b are also separated by the mesa 70. That is, the mesa 70 separates the peripheral regions A and B, and electrically separates (insulates) the bottom protection layer 5a and the bottom protection layer 5b. Thus, the source electrode 13 and the current sense electrode 13a are electrically separated from each other. Since the sidewall connection layer 9 is not provided in the separation region, the base region 3 of the mesa 70 is electrically separated from each of the bottom protection layers 5a and 5b.

In a case where the width of the mesa 70 is larger than the width of the mesa between the plurality of trenches 7 in the main cell region or larger than the width of the mesa between the plurality of trenches 7 in the sense cell region, the breakdown voltage of the entire MOSFET decreases. Therefore, the width of the mesa 70 is preferably equal to or less than the width of the mesa between the plurality of trenches 7 in the main cell region and equal to or less than the width of the mesa between the plurality of trenches 7 in the sense cell region. That is, the width of the mesa 70 is equal to or less than the width of the mesa in the main cell region, and is preferably equal to or less than the width of the mesa in the sense cell region. The width of the mesa 70 also depends on the width between the plurality of trenches 7, and is, for example, 1 μm to 5 μm. According to such a configuration, it is possible to suppress a decrease in the breakdown voltage of the entire MOSFET.

The field insulating film 12, the gate oxide film 6, and the interlayer oxide film are provided in this order on the mesa 70. Note that the capacitance electrodes 8a and 8b in the peripheral regions A and B may be provided to protrude to the separation region.

Next, some modification examples of the semiconductor device described above will be described.

### First Modification Example

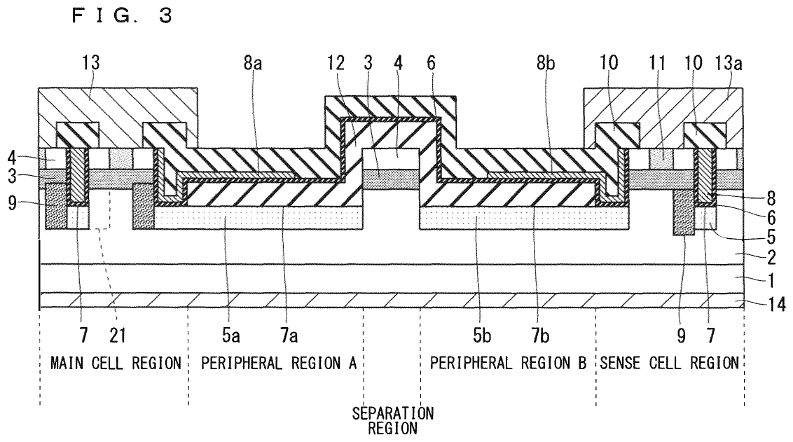

As illustrated in FIG. 3, the sidewall connection layer 9 may be provided only on one sidewall of the trench 7. In a case where the sidewall connection layer 9 is provided only on one sidewall, one of the bottom protection layers 5a and 5b do not need to be connected to the sidewall connection layer 9. That is, the configuration illustrated in FIG. 3 in which the bottom protection layer 5a is electrically connected to the source electrode 13 but the bottom protection layer 5b is not electrically connected to the current sense electrode 13a may be employed. Alternatively, there may be a configuration (not illustrated) in which the bottom protection layer 5a is not electrically connected to the source electrode 13, but the bottom protection layer 5b is electrically connected to the current sense electrode 13a. Even with these configurations, an energy loss during a switching operation can be reduced to some extent.

In the configuration in FIG. 3, the bottom protection layer 5b that is not connected to the sidewall connection layer 9 may extend in the in-plane direction to be connected to the bottom protection layer 5 in the sense cell region connected to the sidewall connection layer 9. Similarly, in a configuration not illustrated, the bottom protection layer 5a that is not connected to the sidewall connection layer 9 may extend in the in-plane direction to be connected to the bottom protection layer 5 in the main cell region connected to the sidewall connection layer 9.

An impurity region 21 (a region indicated by a dotted line in FIG. 3) that is in contact with a sidewall on one side of the trench 7 on which the sidewall connection layer 9 is not provided and has a higher n-type impurity concentration than that of the drift layer 2 may be provided in at least one of the main cell region or the sense region. According to such a configuration, the on-resistance of at least one of the main cell region or the sense region can be reduced.

### Second Modification Example

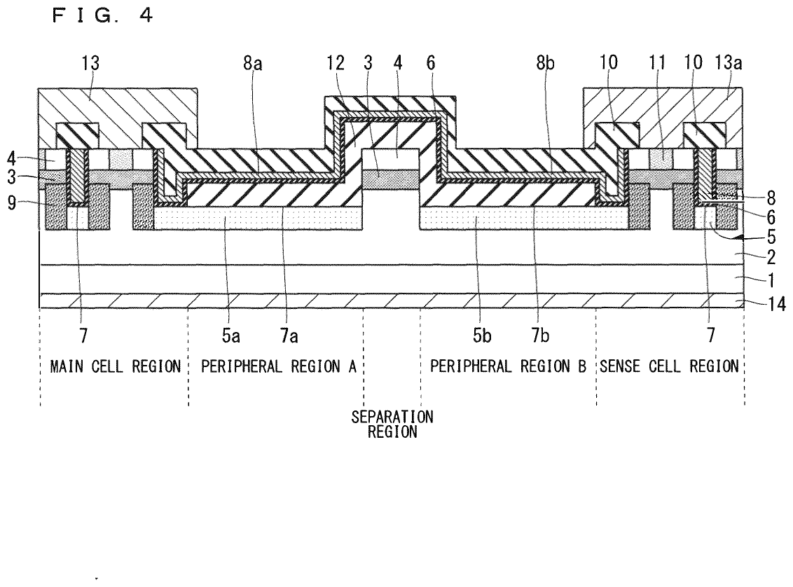

In FIG. 2, the capacitance electrodes 8a and 8b are separated in the separation region, but the present invention is not limited thereto. For example, as illustrated in FIG. 4, the capacitance electrodes 8a and 8b may extend to the separation region and be connected to each other.

### Third Modification Example

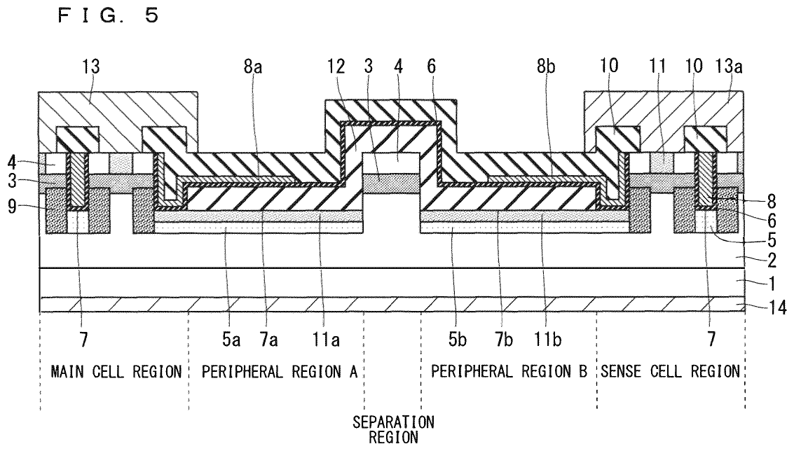

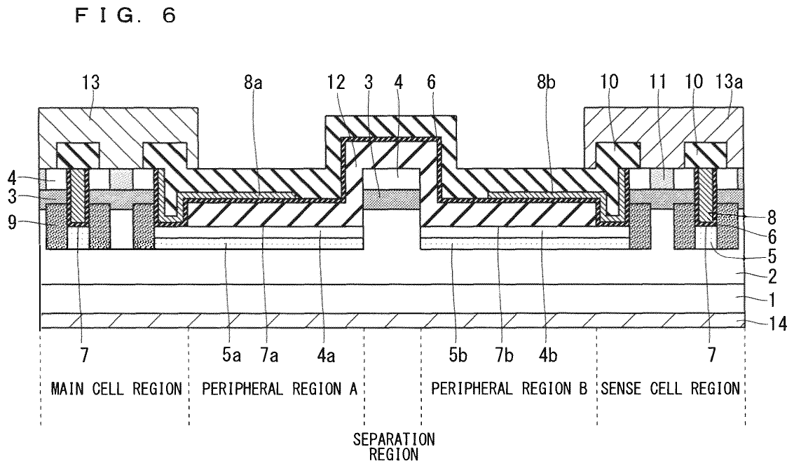

As illustrated in FIGS. 5 and 6, a p-type low-resistance layer 11a or an n-type low-resistance layer 4a that is in contact with the bottom protection layer Sa in the peripheral region A and has a lower resistance than that of the bottom protection layer 5a may be provided. Similarly, a p-type low-resistance layer 11b or an n-type low-resistance layer 4b that is in contact with the bottom protection layer 5b in the peripheral region B and has a resistance lower than that of the bottom protection layer 5b may be provided.

The low-resistance layers 11a and 11b may be high-concentration impurity layers similar to the well contact layer 11 or may be high-concentration impurity layers having impurity concentrations or impurity depth profiles different from those of the well contact layer 11 as long as the low-resistance layers 11a and 11b have an impurity concentration higher than that of the bottom protection layers 5a and 5b. The low-resistance layers 4a and 4b may be high-concentration impurity layers similar to the source region 4 or high-concentration impurity layers having impurity concentrations or impurity depth profiles different from those of the source region 4 as long as the low-resistance layers 4a and 4b have an impurity concentration higher than the bottom protection layers 5a and 5b.

In the configuration in which the low-resistance layers 4a and 11a are provided on the surface of the bottom protection layer 5a or the like, a sheet resistance of a path through which a displacement current flows among the bottoms of the trenches 7a in the peripheral region A can be reduced, and thus a voltage generated by the influence of the displacement current can be reduced. Similarly, in the configuration in which the low-resistance layers 4b and 11b are provided on the surface of the bottom protection layer 5b or the like, a sheet resistance of a path through which a displacement current flows among the bottoms of the trenches 7b in the peripheral region B can be reduced, and thus a voltage generated by the influence of the displacement current can be reduced.

### <Manufacturing Method>

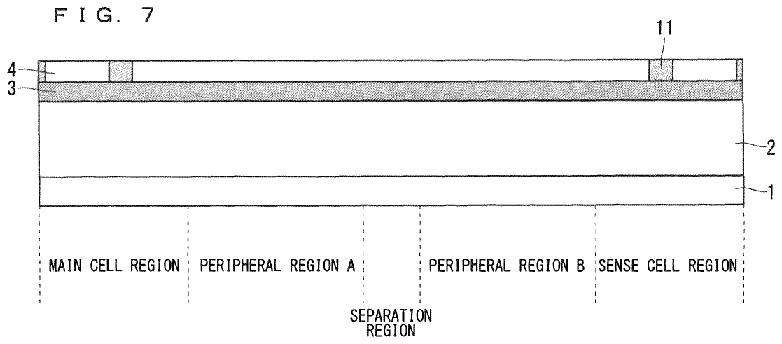

Hereinafter, a method of manufacturing the MOSFET according to the first embodiment will be described. FIGS. 7 to 13 are schematic sectional views illustrating respective steps. Note that materials exemplified in the following description may be changed to materials having equivalent functions as appropriate.

First, an epitaxial layer (semiconductor layer) is formed on the SiC substrate 1. For example, a low-resistance n-type SiC substrate 1 having a 4H polytype is prepared, and an epitaxial layer to be the n-type drift layer 2 is epitaxially grown thereon by using a chemical vapor deposition (CVD) method. The n-type impurity concentration of the drift layer 2 is, for example, 1×10¹⁴ cm⁻³ to 1×10¹⁷ cm⁻³, and a thickness thereof is, for example, to 200 μm.

Next, a predetermined dopant is ion-implanted into an upper surface of the epitaxial layer to form the base region 3 and the source region 4.

The base region 3 is formed through ion implantation of a p-type impurity. A depth of ion implantation of the p-type impurity is in a range not exceeding a thickness of the epitaxial layer, and is, for example, about 0.5 to 3 μm. A p-type impurity concentration to be ion-implanted is higher than the n-type impurity concentration of the epitaxial layer. The p-type impurity concentration of the base region 3 is, for example, 1×10¹⁷ cm⁻³ to 1×10²⁰ cm⁻³. A region of the epitaxial layer deeper than the implantation depth of p-type impurity ions remains as the n-type drift layer 2. The base region 3 may be formed through p-type epitaxial growth. An impurity concentration and a thickness of the base region 3 in this case are similar to those in the case of being formed through ion implantation.

The source region 4 is formed through ion implantation of an n-type impurity into the upper surface of the base region 3. A depth of ion implantation of the n-type impurity is smaller than the thickness of the base region 3. An n-type impurity concentration to be ion-implanted is equal to or higher than the p-type impurity concentration of the base region 3. The n-type impurity concentration of the source region 4 is, for example, 1×10²¹ cm⁻³ or less. The order of ion implantation for forming the p-type and n-type regions does not need to be as described above as long as the structure illustrated in FIG. 2 is finally obtained.

Next, the p-type well contact layer 11 is formed through ion implantation into the source region 4 (refer to FIG. 7). The p-type impurity concentration of the well contact layer 11 is, for example, 1×10¹⁹ cm⁻³ to 1×10²² cm⁻³ or less. By forming the well contact layer 11 to have a thickness equal to or larger than the thickness of the source region 4, the well contact layer 11 is in reliable contact with the base region 3.

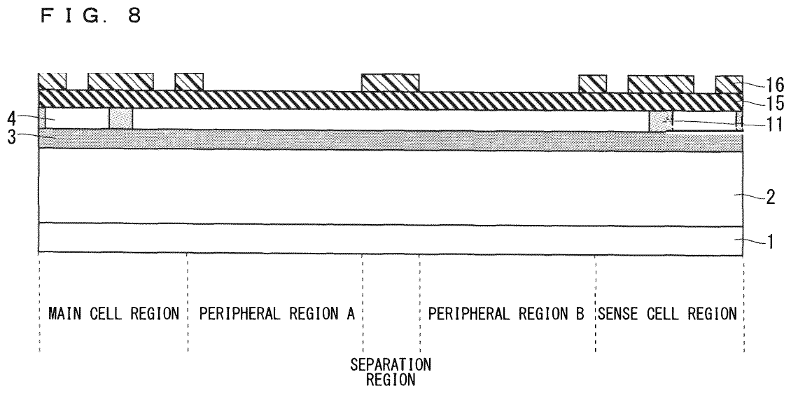

Subsequently, the silicon oxide film 15 with about 1 to 3 μm is deposited on the upper surface of the epitaxial layer, and an etching mask 16 made of a resist material is formed thereon (refer to FIG. 8). The etching mask 16 is formed in a pattern in which formation regions of the trenches 7, 7a, and 7b are opened by using a photolithography technique. Then, a reactive ion etching (RIE) process is performed by using the etching mask 16 as a mask to pattern the silicon oxide film 15. That is, the pattern of the etching mask 16 is transferred to the silicon oxide film 15. The patterned silicon oxide film 15 is used as an etching mask in the next step.

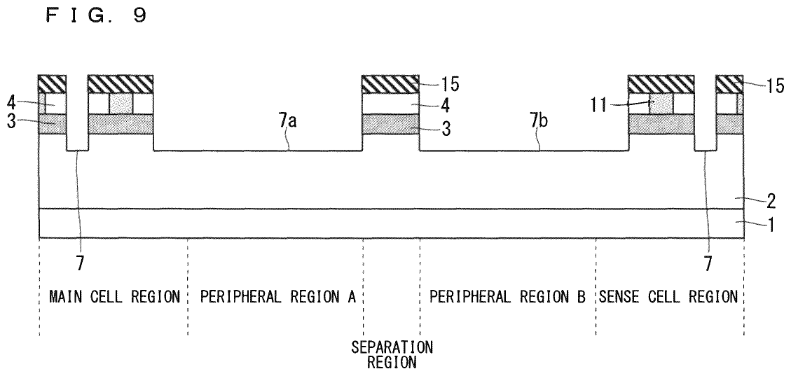

RIE is performed by using the patterned silicon oxide film 15 as a mask to form the trenches 7, 7a, and 7b that penetrate the source region 4 and the base region 3 and reach the drift layer 2 (refer to FIG. 9). The depth of the trenches 7, 7a, and 7b is equal to or greater than the depth of the base region 3, and the thickness thereof is, for example, about 1.0 to 6.0 μm.

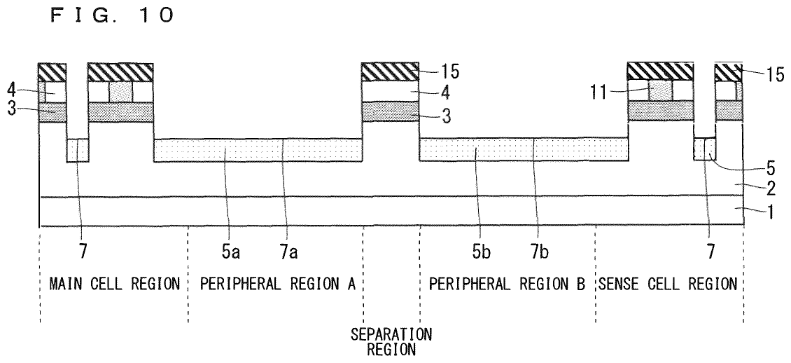

Thereafter, an implantation mask having a pattern in which at least a part of the trenches 7, 7a, and 7b is opened is formed, and ion implantation is performed by using the implantation mask as a mask to form the p-type bottom protection layers 5, 5 a, and 5b at the bottoms of the trenches 7 (refer to FIG. 10). The p-type impurity concentration of the bottom protection layers 5, 5a, and 5b is, for example, 1×10¹⁷ cm⁻³ to 1×10¹⁹ cm⁻³, and the thickness thereof is, for example, 0.1 to 2.0 μm. The impurity concentration of the bottom protection layers 5, 5a, and 5b is determined on the basis of an electric field applied to the gate oxide film 6 when a rated voltage is applied between the drain and the source of the MOSFET.

As illustrated in FIG. 10, the silicon oxide film 15 that is an etching mask for forming the trenches 7, 7a, and 7b, may be used as an implantation mask of the bottom protection layers 5, 5a, and 5b. In this case, the number of manufacturing steps and cost can be reduced. In a case where the silicon oxide film 15 is used as an implantation mask of the bottom protection layers 5, 5a, and 5b, it is necessary to adjust a thickness of the silicon oxide film 15 and etching conditions so that the silicon oxide film 15 having a certain thickness remains after the trenches 7, 7a, and 7b are formed. Since the bottom protection layer 5 forms a pn junction with the drift layer 2, the pn junction can also be used as a diode similarly to the pn junction between the base region 3 and the drift layer 2.

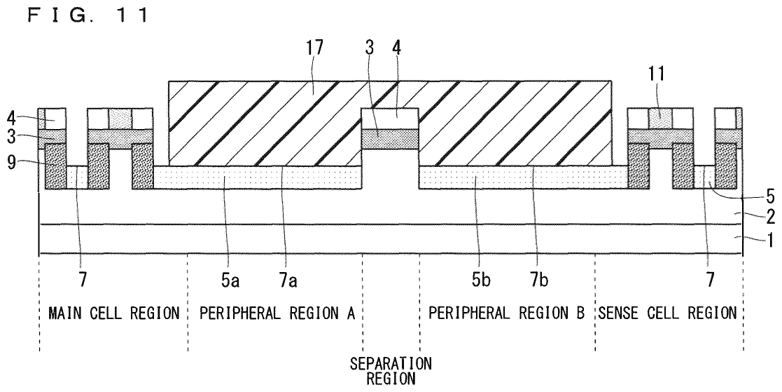

After the implantation mask and the silicon oxide film 15 are removed, a p-type impurity is ion-implanted obliquely into the sidewalls of the trenches 7, 7a, and 7b by using the implantation mask 17 opened at any pitch in the depth direction of the cross section, thereby forming the sidewall connection layer 9 (refer to FIG. 11). In the separation region, the drift layer 2 and the like in the separation region are covered with the implantation mask 17 such that the sidewall connection layer 9 is not formed. The p-type impurity concentration of the sidewall connection layer 9 is, for example, 1×10¹⁷ cm⁻³ to 1×10¹⁹ cm 3, and the thickness thereof is, for example, 0.1 to 2.0 μm. The sidewall connection layer 9 may be formed by performing ion implantation from the surface of the epitaxial layer by using a mask (not illustrated). In this case, it is desirable to perform ion implantation before the trenches 7, 7a, and 7b are opened. A concentration and a thickness of the sidewall connection layer 9 in the case of using ion implantation from the surface of the epitaxial layer are similar to those in the case of using ion implantation from the sidewalls of the trenches 7, 7a, and 7b.

The order of formation of the n-type and p-type layers and regions formed in the drift layer 2 is not particularly limited. The n-type impurity may be, for example, nitrogen (N) or phosphorus (P), and the p-type impurity may be, for example, aluminum (Al) or boron (B).

After the implantation mask 17 is removed, annealing for activating the impurities ion-implanted so far is performed by using a heat treatment apparatus. This annealing is performed in an inert gas atmosphere such as argon (Ar) gas or in a vacuum at a temperature of 1300 to 1900ºC for a processing time of 30 seconds to one hour.

Subsequently, an insulating film is formed by using a thermal oxidation method, a chemical vapor deposition (CVD) method, or the like, and then wet etching or dry etching is performed to form the field insulating film 12 for protecting a termination region and a peripheral region.

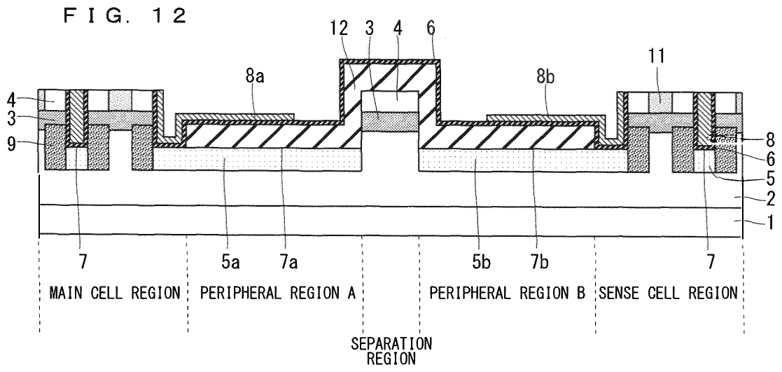

Next, a silicon oxide film is formed on the entire upper surface of the epitaxial layer including the inner surface of the trench 7. The silicon oxide film may be formed by thermally oxidizing the upper surface of the epitaxial layer, or may be deposited on the epitaxial layer. A polysilicon film is deposited on the silicon oxide film by using a reduced pressure CVD method, and the silicon oxide film and the polysilicon film are patterned or etched back to form the gate oxide film 6, the polysilicon electrode 8, and the capacitance electrodes 8a and 8b (refer to FIG. 12).

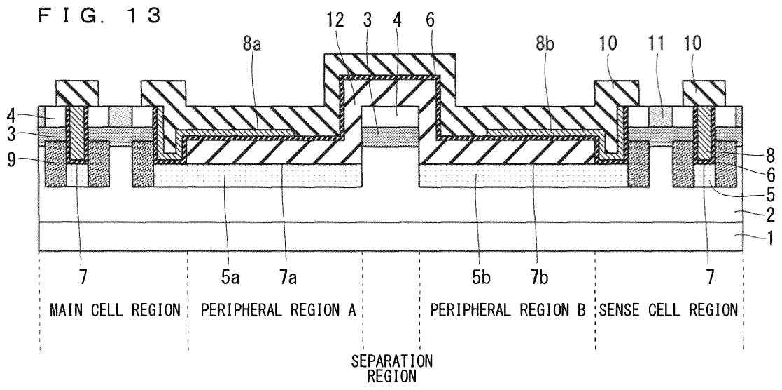

Subsequently, an interlayer oxide film is formed on the entire upper surface of the structure formed so far by using a reduced pressure CVD method, and the base region 3, the source region 4, the polysilicon electrode 8, and the capacitance electrodes 8a and 8b are covered with the interlayer oxide film. By patterning the interlayer oxide film, an interlayer oxide film 10 having a contact hole reaching the base region 3 and the source region 4 is formed (refer to FIG. 13).

Subsequently, an ohmic electrode (not illustrated) is formed on the epitaxial layer exposed to the bottom of the contact hole of the interlayer oxide film 10. For example, a metal film containing nickel (Ni) as a main component is formed on the entire upper surface of the structure formed so far, and the metal film is reacted with silicon carbide of the epitaxial layer through heat treatment at 600 to 1100° ° C. to form a silicide film as an ohmic electrode. Thereafter, an unreacted metal film remaining on the interlayer oxide film 10 or the like is removed through wet etching using a nitric acid, a sulfuric acid, a hydrochloric acid, a mixed solution thereof with a hydrogen peroxide solution, or the like. After the metal film remaining on the interlayer oxide film 10 is removed, heat treatment may be performed again. In this case, an ohmic contact having a lower contact resistance is formed by performing heat treatment at a higher temperature than in the previous heat treatment. In this case, if the interlayer oxide film 10 is too thin, reaction between the polysilicon electrode 8 and the metal film occurs, and thus the interlayer oxide film 10 desirably has a sufficient thickness.

Next, the source electrode 13 and the current sense electrode 13a are formed on the interlayer oxide film 10 and in the contact hole by depositing an electrode material such as an Al alloy. Finally, the drain electrode 14 is formed by depositing an electrode material such as an Al alloy on the lower surface of the SiC substrate 1. As described above, the MOSFET according to the first embodiment illustrated in FIGS. 1 and 2 is obtained.

### Summary of First Embodiment

According to the first embodiment as described above, the bottom protection layer 5a is electrically connected to the source electrode 13, and the bottom protection layer 5b is electrically connected to the current sense electrode 13a. According to such a configuration, since the bottom protection layers 5a and 5b are not in a floating potential state, an energy loss during a switching operation can be reduced.

Although the MOSFET in which the drift layer 2 and the SiC substrate 1 (buffer layer) have the same conductivity type has been described above, the above configuration is also applicable to an IGBT in which the drift layer 2 and the SiC substrate 1 have different conductivity types. For example, when the SiC substrate 1 is of a p-type, a configuration of an IGBT is obtained. In this case, the source region 4 and the source electrode 13 of the MOSFET respectively correspond to an emitter region and an emitter electrode of the IGBT, and the drain electrode 14 of the MOSFET corresponds to a collector electrode.

In the above description, the semiconductor device including SiC that is one of the wide band gap semiconductors has been described, but the above configuration is also applicable to a semiconductor device including other wide band gap semiconductors such as a gallium nitride (GaN)-based material and diamond. The above-described decrease in the energy loss during the switching operation is particularly effective in a semiconductor device including a wide band gap semiconductor capable of using a high voltage.

### Second Embodiment

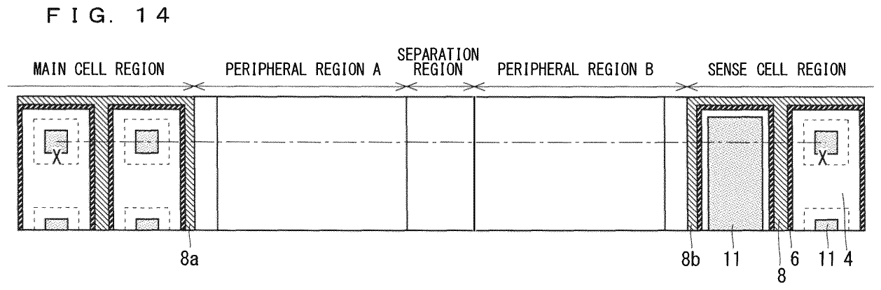

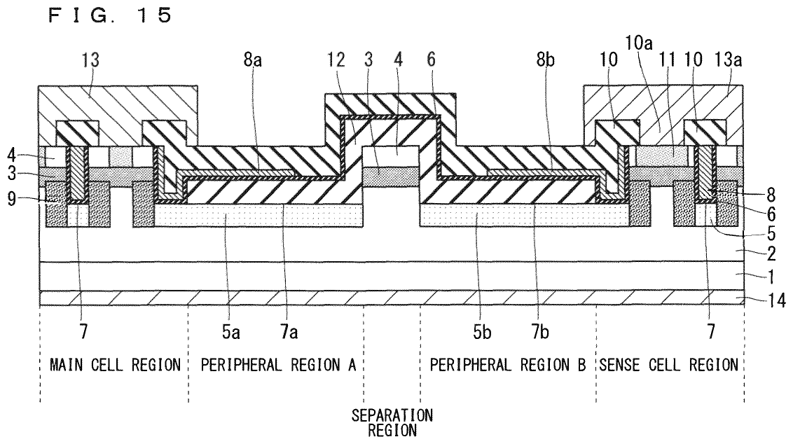

FIG. 14 is a schematic plan view illustrating a configuration of a semiconductor device according to a second embodiment, and FIG. 15 is a schematic sectional view taken along line X-X in FIG. 14.

As illustrated in FIG. 15, the second embodiment is different from the first embodiment in that both ends of a well contact layer 11 in a sense cell region are located outside both ends of a contact hole 10a adjacent to the well contact layer 11 in any cross section. That is, in the second embodiment, there is a cross section in which the contact hole 10a of the interlayer oxide film 10 in the sense cell region is in contact with the well contact layer 11 without being in contact with the source region 4. Note that such a wide well contact layer 11 can be formed by changing the photolithography mask pattern used at the time of forming the well contact layer 11 from that in the first embodiment.

In order to suppress heat generation due to an overcurrent in the sense cell region, it is conceivable to reduce an area of a portion through which a current flows in the sense cell region. However, the smaller the area of the sense cell region, the lower the static electricity tolerance. The static electricity tolerance is an amount indicating tolerance to a voltage applied to the gate oxide film 6 when static electricity is generated, and a voltage applied to the gate oxide film 6 is inversely proportional to the magnitude of a capacitance between a gate electrode and a current sense electrode. Therefore, in order to increase the static electricity tolerance of the sense cell region, a voltage applied to the gate oxide film 6 may be reduced by increasing the capacitance between the gate electrode and the current sense electrode.

As a configuration for increasing the capacitance between the gate electrode and the current sense electrode, a configuration for increasing a capacitance area between the gate electrode and the current sense electrode is conceivable. Therefore, in the second embodiment, as described above, the contact hole 10a of the interlayer oxide film 10 in the sense cell region is configured to partially have a cross section in contact with the well contact layer 11 without being in contact with the source region 4.

According to such a configuration, a current can be detected in a cross section in which the contact hole 10a is in contact with the source region 4. In a cross section in which the contact hole 10a is in contact with the well contact layer 11 without being in contact with the source region 4, a capacitance between the gate electrode and the current sense electrode can be increased. As described above, the static electricity tolerance of the sense cell region can be increased, and an area of the portion through which a current flows in the sense cell region can be reduced.

Note that the well contact layer 11 having a large width as described above may be provided for any contact hole 10a in any cross section. For example, the well contact layer 11 may be provided on the entire lower surface of at least one contact hole 10a, or the well contact layer 11 may be provided on the entire lower surface of the contact hole 10a for every certain number of cycles. In any cross section, the entire source region 4 may be replaced with the well contact layer 11, or the well contact layer 11 may be formed at the bottom of the trench 7 in contact with the source region 4.

### Summary of Second Embodiment

According to the second embodiment as described above, in any cross section, both ends of the well contact layer 11 in the sense cell region are located outside both ends of the contact hole 10a adjacent to the well contact layer 11. According to such a configuration, the static electricity tolerance of the sense cell region can be increased, and an area of a portion through which a current flows in the sense cell region can be reduced.

### Third Embodiment

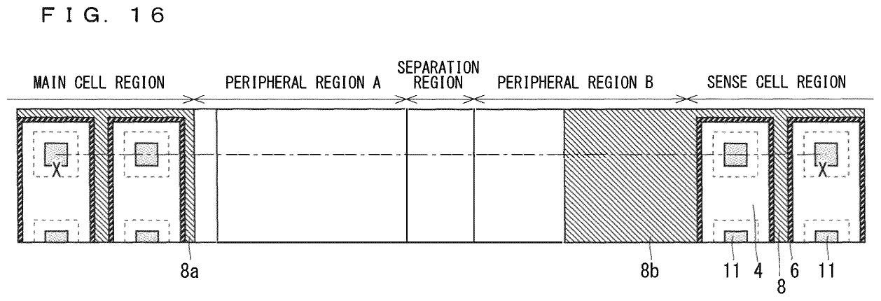

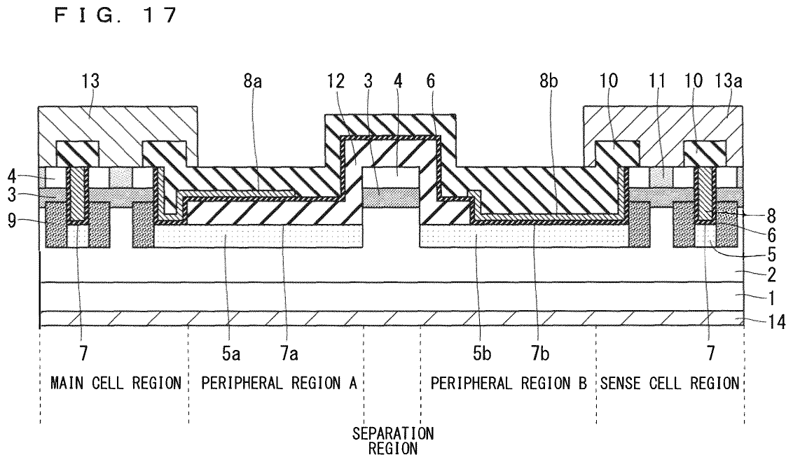

FIG. 16 is a schematic plan view illustrating a configuration of a semiconductor device according to a third embodiment, and FIG. 17 is a schematic sectional view taken along line X-X in FIG. 16.

As described in the second embodiment, in order to increase the static electricity tolerance of the sense cell region, a configuration in which a capacitance area between the gate electrode and the current sense electrode is increased is considered. Here, since the capacitance electrode 8b is provided on the bottom protection layer 5b of the peripheral region B via the gate oxide film 6 that is an insulating film, the capacitance electrode 8b and the bottom protection layer 5b form a capacitor. Since the capacitance electrode 8b is connected to the polysilicon electrode 8 that is a gate electrode, and the bottom protection layer 5b is electrically connected to the current sense electrode 13a, a capacitance area between the gate electrode and the current sense electrode can be increased by increasing areas of the capacitance electrode 8b and the bottom protection layer 5b.

In the configuration in FIG. 2 of the first embodiment, a capacitor including the capacitance electrode 8b and the bottom protection layer 5b is formed in a part of the sense cell region. However, in the peripheral region B, since a distance between the capacitance electrode 8b and the bottom protection layer 5b is increased by the field insulating film 12, a capacitor is not substantially formed. Therefore, in the first embodiment, the static electricity tolerance of the sense cell region can be increased by the capacitor by using the capacitance electrode 8b and the bottom protection layer 5b, but the effect is relatively small since the capacitor is formed only in a part of the sense cell region.

In contrast, in the third embodiment in FIG. 17, in the peripheral region B, the field insulating film 12 is provided only in a portion adjacent to the separation region, and the capacitance electrode 8b is provided to extend to the portion adjacent to the separation region. As a result, since the capacitor including the capacitance electrode 8b and the bottom protection layer 5b is also formed in the peripheral region B, the static electricity tolerance of the sense cell region can be increased, and an area of the portion through which a current flows in the sense cell region can be reduced.

Note that the semiconductor device according to the third embodiment as described above can be formed by changing the photolithography mask pattern used at the time of forming the capacitive electrode 8b and the field insulating film 12 from that in the first embodiment. Since various shapes may be used as a shape of the capacitor in a plan view, the shape of the capacitor in a plan view does not need to be a stripe shape as illustrated in FIG. 16.

### <Summary of Third Embodiment

According to the third embodiment as described above, a capacitor including the capacitance electrode 8b and the bottom protection layer 5b can be formed in the peripheral region B. According to such a configuration, the static electricity tolerance of the sense cell region can be increased, and an area of a portion through which a current flows in the sense cell region can be reduced.

### Fourth Embodiment

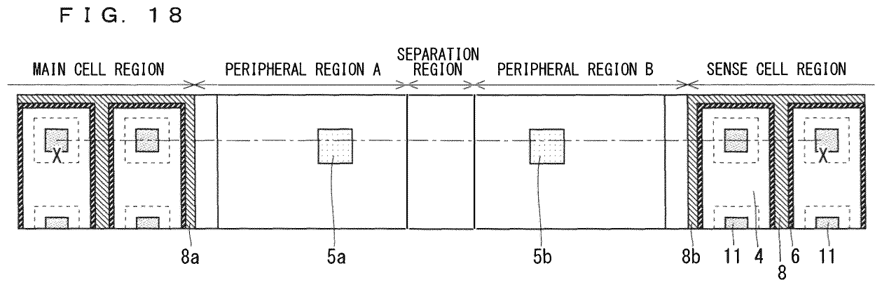

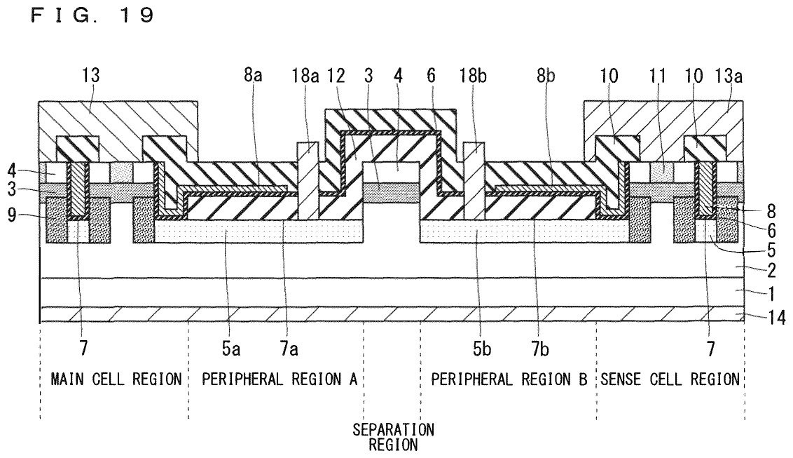

FIG. 18 is a schematic plan view illustrating a configuration of a semiconductor device according to a fourth embodiment, and FIG. 19 is a schematic sectional view taken along line X-X in FIG. 18.

As described in the first embodiment, the bottom protection layers 5a and 5b of the peripheral regions A and B are respectively connected to the source electrode 13 and the current sense electrode 13a via the sidewall connection layers 9. Since a distance between the bottom protection layers 5a and 5b and the sidewall connection layer 9 becomes relatively long in the vicinity of the boundary between the separation region and each of the peripheral regions A and B, a displacement current path at the time of switching becomes long, and a high voltage due to the displacement current is generated, so that a failure may occur in a device.

Therefore, the fourth embodiment is different from the first embodiment in that connection electrodes 18a and 18b are respectively provided in the peripheral regions A and B in order to suppress generation of a high voltage due to a displacement current. In the example in FIG. 19, an ohmic electrode (not illustrated) is provided in a contact hole provided in the interlayer oxide film 10 and the field insulating film 12 in the peripheral regions A and B. In the fourth embodiment, the connection electrodes 18a and 18b have the ohmic electrodes, and are respectively provided on the bottom protection layers 5a and 5b. Although not illustrated, the connection electrodes 18a and 18b are respectively connected to the source electrode 13 and the current sense electrode 13a. As described above, according to the configuration in which the connection electrode 18a connects the bottom protection layer 5a and the source electrode 13, and the connection electrode 18a connects the bottom protection layer 5b and the current sense electrode 13a, a displacement current path at the time of switching can be shortened, and generation of a high voltage can be suppressed.

Note that the contact holes provided with the connection electrodes 18a and 18b as described above can be formed by changing the photolithography mask pattern used at the time of forming the interlayer oxide film 10 from that in the first embodiment. Since various shapes may be used as shapes of the connection electrodes 18a and 18b in a plan view, the shapes of the connection electrodes 18a and 18b in a plan view do not need to be island shapes as illustrated in FIG. 18, and may be, for example, stripe shapes. Although both the connection electrodes 18a and 18b are provided in the above description, only one of the connection electrodes 18a and 18b may be provided.

### Summary of Fourth Embodiment

According to the fourth embodiment as described above, the connection electrodes 18a and 18b can suppress generation of a high voltage due to a displacement current in the peripheral regions A and B, and thus reliability of a device can be enhanced.

### Fifth Embodiment

In a fifth embodiment, the semiconductor device according to the above-described first to fourth embodiments is applied to a power conversion apparatus. Although the present disclosure is not limited to a specific power conversion apparatus, a case where the present disclosure is applied to a three-phase inverter will be described below as the fifth embodiment.

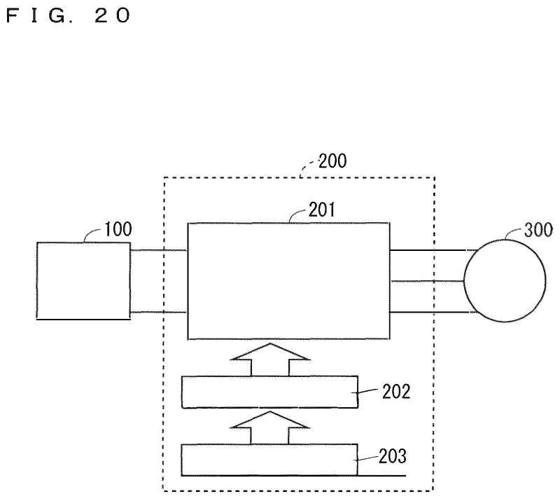

FIG. 20 is a block diagram illustrating a configuration of a power conversion system to which a power conversion apparatus according to the fifth embodiment is applied.

The power conversion system illustrated in FIG. 20 includes a power supply 100, a power conversion apparatus 200, and a load 300. The power supply 100 is a DC power supply, and supplies DC power to the power conversion apparatus 200. The power supply 100 may be configured with various constituents, for example, a DC system, a solar cell, and a storage battery, or may be configured with a rectifier circuit or an AC/DC converter connected to an AC system. The power supply 100 may be configured with a DC/DC converter that converts DC power output from a DC system into predetermined power.

The power conversion apparatus 200 is a three-phase inverter connected between the power supply 100 and the load 300, converts DC power supplied from the power supply 100 into AC power, and supplies the AC power to the load 300. As illustrated in FIG. 20, the power conversion apparatus 200 includes a main conversion circuit 201 that converts DC power into AC power and outputs the AC power, a drive circuit 202 that outputs a drive signal for driving each switching element of the main conversion circuit 201, and a control circuit 203 that outputs a control signal for controlling the drive circuit 202 to the drive circuit 202.

The drive circuit 202 performs off-control on each normally-off type switching element by setting a voltage of a gate electrode and a voltage of a source electrode to the same potential.

The load 300 is a three-phase motor driven by the AC power supplied from the power conversion apparatus 200. The load 300 is not limited to a specific application, but is a motor mounted on various electric devices, and is used as, for example, a motor for a hybrid vehicle, an electric vehicle, a railway vehicle, an elevator, or an air conditioner.

Hereinafter, details of the power conversion apparatus 200 will be described. The main conversion circuit 201 includes a switching element and a freewheeling diode (not illustrated), converts DC power supplied from the power supply 100 into AC power through switching of the switching element, and supplies the AC power to the load 300. Although there are various specific circuit configurations of the main conversion circuit 201, the main conversion circuit 201 according to the fifth embodiment is a two-level three-phase full bridge circuit, and can include six switching elements and six freewheeling diodes reversely parallel to the respective switching elements. A semiconductor device manufactured by using the method of manufacturing a semiconductor device according to any one of the above-described first to fourth embodiments is applied to each switching element of the main conversion circuit 201. The six switching elements are connected in series for every two switching elements to configure upper and lower arms, and each of the upper and lower arms configures one phase (a U-phase, a V-phase, or a W-phase) of the full bridge circuit. Output terminals of the upper and lower arms, that is, three output terminals of the main conversion circuit 201 are connected to the load 300.

The drive circuit 202 generates a drive signal for driving the switching element of the main conversion circuit 201, and supplies the drive signal to a control electrode of the switching element of the main conversion circuit 201. Specifically, in response to the control signal from the control circuit 203 that will be described later, a drive signal for turning on the switching element and a drive signal for turning off the switching element are output to the control electrode of each switching element. In a case where the switching element is maintained in an ON state, the drive signal is a voltage signal (ON signal) larger than a threshold voltage of the switching element, and in a case where the switching element is maintained in an OFF state, the drive signal is a voltage signal (OFF signal) smaller than the threshold voltage of the switching element.

The control circuit 203 controls the switching elements of the main conversion circuit 201 such that desired power is supplied to the load 300. Specifically, a time (ON time) during which each switching element of the main conversion circuit 201 is to be turned on is calculated on the basis of power to be supplied to the load 300. For example, the main conversion circuit 201 can be controlled through PWM control for modulating an ON time of the switching element according to a voltage to be output. A control command (control signal) is output to the drive circuit 202 such that an ON signal is output to the switching element to be turned on at each time point, and an OFF signal is output to the switching element to be turned off at each time point. The drive circuit 202 outputs an ON signal or an OFF signal as a drive signal to the control electrode of each switching element according to the control signal.

In the power conversion apparatus according to the present embodiment, since the silicon carbide semiconductor device according to the first to fourth embodiments is applied as the switching element of the main conversion circuit 201, it is possible to implement a power conversion apparatus with low loss and enhanced reliability of high-speed switching.

In the present embodiment, an example in which the present disclosure is applied to a two-level three-phase inverter has been described, but the present disclosure is not limited thereto, and can be applied to various power conversion apparatuses. In the present embodiment, the two-level power conversion apparatus is used, but a three-level or multi-level power conversion apparatus may be used, or the present disclosure may be applied to a single-phase inverter in a case where power is supplied to a single-phase load. In a case where power is supplied to a DC load or the like, the present disclosure can also be applied to a DC/DC converter or an AC/DC converter.

The power conversion apparatus to which the present disclosure is applied is not limited to the case where the load described above is a motor, and may be used as, for example, a power supply apparatus of an electric discharge machine, a laser beam machine, an induction heating cooker, or a non-contact power feeding system, and can also be used as a power conditioner of a solar power generation system, a power storage system, or the like.

Note that the embodiments and the modification examples can be freely combined, and the embodiments and the modification examples can be appropriately modified or omitted as appropriate.

The above description is illustrative and not restrictive in all aspects. It is understood that numerous modification examples not exemplified can be assumed.

### EXPLANATION OF REFERENCE SIGNS

2: drift layer
3: base region
4: source region
4a, 4b, 11a, 11b: low-resistance layer
5, 5a, 5b: bottom protection layer
6: gate oxide film
7, 7a, 7b: trench
8: polysilicon electrode
8a, 8b: capacitance electrode
9: sidewall connection layer
10a: contact hole
11: well contact layer
13: source electrode
13a: current sense electrode
21: impurity region
70: mesa
201: main conversion circuit
202: drive circuit
203: control circuit

1. A semiconductor device comprising:
a main cell region and a sense cell region that are separated from each other;
a first peripheral region that is adjacent to the main cell region between the main cell region and the sense cell region;
a second peripheral region that is adjacent to the sense cell region between the main cell region and the sense cell region; and
a separation region that separates the first peripheral region and the second peripheral region from each other, wherein
the main cell region, the first peripheral region, the separation region, the second peripheral region, and the sense cell region include a drift layer of a first conductivity type,
each of the main cell region and the sense cell region further includes
a body region of a second conductivity type that is provided on the drift layer,
a source region of the first conductivity type that is provided on the body region,
a first trench that penetrates the body region and the source region and is partially in contact with the drift layer,
a gate electrode that is provided in the first trench via a gate insulating film,
a first bottom protection layer of the second conductivity type that is provided at a bottom of the first trench, and
a connection layer of the second conductivity type that is provided along at least a part of a sidewall of the first trench and connects the first bottom protection layer and the body region,
the main cell region further includes a source electrode that is connected to the source region,
the sense cell region further includes a current sense electrode that is connected to the source region and separate from the source electrode,
the first peripheral region further includes
a second trench that is provided above the drift layer and is wider than the first trench; and
a second bottom protection layer of the second conductivity type that is provided at the bottom of the second trench,
the second peripheral region further includes
a third trench that is provided above the drift layer and is wider than the first trench, and
a third bottom protection layer of the second conductivity type that is provided at the bottom of the third trench, and
the second bottom protection layer is electrically connected to the source electrode, the third bottom protection layer is electrically connected to the current sense electrode, or the second bottom protection layer and the third bottom protection layer are respectively electrically connected to the source electrode and the current sense electrode.

2. The semiconductor device according to claim 1, wherein
a depth of the second trench, a depth of the third trench, a depth of the first trench in the main cell region, and a depth of the first trench in the sense cell region are the same.

3. The semiconductor device according to claim 1, wherein
a mesa that electrically separates the second bottom protection layer from the third bottom protection layer is provided in the separation region.

4. The semiconductor device according to claim 3, wherein
a width of the mesa is equal to or less than a width between a plurality of the first trenches in the main cell region and is equal to or less than a width between a plurality of the first trenches in the sense cell region.

5. The semiconductor device according to claim 1, wherein
the connection layer is provided along a sidewall on one side of the first trench, and
the semiconductor device further comprises an impurity region that is in contact with a sidewall on one side of the first trench on which the connection layer is not provided and has an impurity concentration of the first conductivity type higher than an impurity concentration of the drift layer.

6. The semiconductor device according to claim 1, further comprising:
a low-resistance layer of the second conductivity type that is provided in contact with at least one of the second bottom protection layer or the third bottom protection layer and has a resistance lower than a resistance of the at least one layer.

7. The semiconductor device according to claim 1, further comprising:
a low-resistance layer of the first conductivity type that is provided in contact with at least one of the second bottom protection layer or the third bottom protection layer and has a resistance lower than a resistance of the at least one layer.

8. The semiconductor device according to claim 1, further comprising:
a well contact layer that is provided on the body region in the sense cell region and has an impurity concentration of the second conductivity type higher than an impurity concentration of the body region, wherein
in any cross section, both ends of the well contact layer are located outside both ends of a contact hole adjacent to the well contact layer.

9. The semiconductor device according to claim 1, further comprising:
a capacitance electrode that is provided on the third bottom protection layer with an insulating film interposed therebetween, wherein
the capacitance electrode is connected to the gate electrode in the sense cell region.

10. The semiconductor device according to claim 1, further comprising:
a connection electrode that is provided on the third bottom protection layer and connected to the current sense electrode.

11. The semiconductor device according to claim 1, wherein
the drift layer includes a wide band gap semiconductor.

12. A power conversion apparatus comprising:
a main conversion circuit that includes the semiconductor device according to claim 1 and converts and outputs input power;
a drive circuit that outputs a drive signal for driving the semiconductor device to the semiconductor device; and
a control circuit that outputs a control signal for controlling the drive circuit to the drive circuit.
